(19) United States
(12) Patent Application Publication
(10) Pub. No.: US 2002/0020866 A1
(43) Pub. Date: Feb. 21, 2002

(54) METHOD FOR MANUFACTURING A CAPACITOR HAVING A TWO-LAYER LOWER ELECTRODE

(76) Inventors: JOO-WON LEE, KYUNGKI-DO (KR); YOUNG-WOOK PARK, KYUNGKI-DO (KR)

Correspondence Address: SKJERVEN MORRILL MACPHERSON LLP, 25 METRO DRIVE, SUITE 700, SAN JOSE, CA, 95110, US

(21) Appl. No.: 09/351,099

(22) Filed: Jul. 8, 1999

(30) Foreign Application Priority Data
Jul. 10, 1998 (KR) 1998-27885
Feb. 5, 1999 (KR) 1999-3960

(51) Int. Cl. H01L 27/108; H01L 29/76; H01L 29/94; H01L 31/119; H01L 21/20

(52) U.S. Cl. 257/301

(57) ABSTRACT

A lower electrode of a capacitor of a semiconductor device according to the present invention is formed of a double film of a material film including a metal and a silicon film. The material film is formed of one selected from the group consisting of a metal film formed of one among Ti, W, Co, Al, Pt, Ru, and Ir, a silicide film of the above metals, an Ir oxide film, and an Ru oxide film. The silicon film may be formed of a hemispherical grain film (HSG—Si film). The lower electrode may be formed to be cylindrical. In the present invention, it is possible to increase Cmin/Cmax value since a material film including a metal is used as the lower electrode, thus reducing the charge depletion.

### BACKGROUND OF THE INVENTION

1. Field of the Invention

The present invention relates to a semiconductor device, and more particularly, to a capacitor in a semiconductor device and a method for manufacturing the same.

2 Description of the Related Art

The advancement of semiconductor device integration has reduced the area allowed for a capacitor in a semiconductor device, and thus a capacitor with a conventional lower electrode made of a polysilicon film can no longer achieve a desired capacitance. Accordingly, a number of capacitor manufacturing methods have been suggested to increase capacitance in highly integrated semiconductor devices such as DRAM. One method uses a thin dielectric film and a dielectric film material with a high dielectric constant and fabricates a lower electrode in the form of a cylinder or a fin.

Developing technologies related to the use of thin dielectric films and dielectric film materials with high dielectric constants has encountered many technological obstacles. For example, a conventional chemical vapor deposition (CVD) of high dielectric constant materials such as PZT (PbZrTiO₃) and BST (BaSrTiO₃) on a curved lower electrode does not produce a dielectric film having a uniform composition. Further, formation of an interface oxide film on and under the dielectric film must be prevented to prevent degradation of the film's dielectric constant, but the preventing oxide formation is difficult to accomplish.

Forming a cylindrical or fin-type lower electrode also has resulted in technological problems that limit the height of the lower electrode. Furthermore, constructing the capacitor using the polysilicon film as the lower electrode generates charge depletion. Accordingly, the ratio Cmin (the minimum value of capacitance)/Cmax (the maximum value of capacitance) decreases. Also, for a polysilicon lower electrode, a subsequent thermal annealing process oxidizes the polysilicon and thus forms an oxide film. As a result, the thickness of an equivalent oxide film as the dielectric film increases, and thus decreases the capacitance in a highly integrated semiconductor device.

### SUMMARY OF THE INVENTION

According to an embodiment of the present invention, a capacitor of a semiconductor device includes a lower electrode, a dielectric film, and an upper electrode. The lower electrode has two layers, a conductive material film and a silicon film. The lower electrode can be cylindrical. The conductive material film can be selected from a group consisting of a metal film comprised of one among Ti, W, Co, Al, Pt, Ru, and Ir, a suicide film of the above metals, and a noble metal film such as an Ir oxide film and an Ru oxide film. The silicon film can be a hemispherical grain (HSG-Si) film.

According to another embodiment of the invention, a method for manufacturing a capacitor of a semiconductor device includes forming a lower electrode with a conductive material film and a silicon film on a semiconductor substrate, forming a dielectric film on the lower electrode, and forming an upper electrode on the dielectric film. The silicon film can be an HSG-Si film. The lower electrode can be cylindrical. The conductive material film can be selected from the group consisting of a metal film comprised of Ti, W, Co, Al, Pt, Ru, or Ir, a silicide film of the metals, an Ir oxide film, and an Ru oxide film.

In the present invention, the material film in the lower electrode, reduces or prevents the charge depletion. Accordingly, it is possible to increase the Cmin/Cmax ratio.

### BRIEF DESCRIPTION OF THE DRAWINGS

The present invention will become more apparent by describing in detail embodiments thereof with reference to the attached drawings in which:

FIG. 1 is a sectional view showing a lower capacitor electrode of a semiconductor device according to an embodiment of the present invention;

FIG. 2 is a sectional view showing a lower capacitor electrode of a semiconductor device according to another embodiment of the present invention;

FIGS. 3 through 6 are sectional views illustrating a method for manufacturing the lower capacitor electrode of FIG. 1; and

FIGS. 7 and 8 are sectional views illustrating a method for manufacturing the lower capacitor electrode of FIG. 2.

Use of same reference symbols in different figures indicates similar or identical items.

### DESCRIPTION OF THE PREFERRED EMBODIMENTS

Hereinafter, embodiments of the present invention are described with reference to the attached drawings. However, the present invention is not restricted to the described embodiments, and it is clearly understood that many variations are possible within the scope and spirit of the present invention.

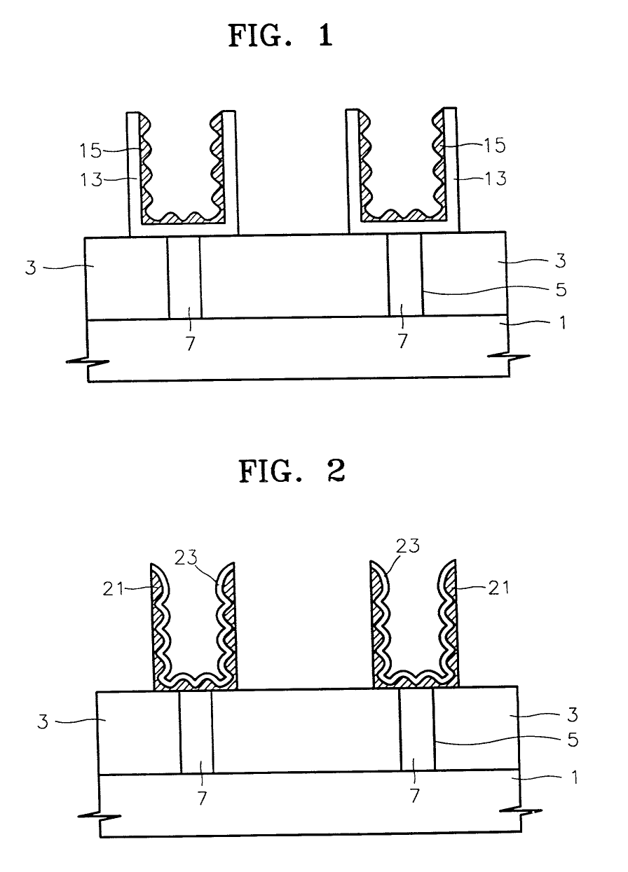

FIG. 1 shows a sectional view of a lower plate of a capacitor of a semiconductor device according to an embodiment of the present invention. To be specific, an insulating film 3 having a contact hole 5 is formed on a semiconductor substrate 1. A buried conductive layer 7 formed in the contact hole 5 connects to the semiconductor substrate 1. A conductive material film 13, which connects to buried conductive layer 7, is formed in a cylindrical form and used as the lower electrode of the capacitor. Conductive material film 13 is formed of a material selected from the group consisting of aluminum, a refractory metal such as Ti, W, and Co, a platinum group metal such as Pt, Ru, Ir and a combination thereof, a platinum group metal oxide such as Ir oxide, Ru oxide and a combination thereof, and silicides of the metals. A silicon film 15, i.e., a hemi-spherical grain film (HSG-Si film) is on an inner wall of conductive material film 13 so as to complete the lower electrode. As a result, the lower electrode of the capacitor is a double layer film that includes the conductive material film 13 and the silicon film 15. A complete capacitor includes a dielectric film (not shown) on the lower electrode and an upper electrode (not shown) on the dielectric film.

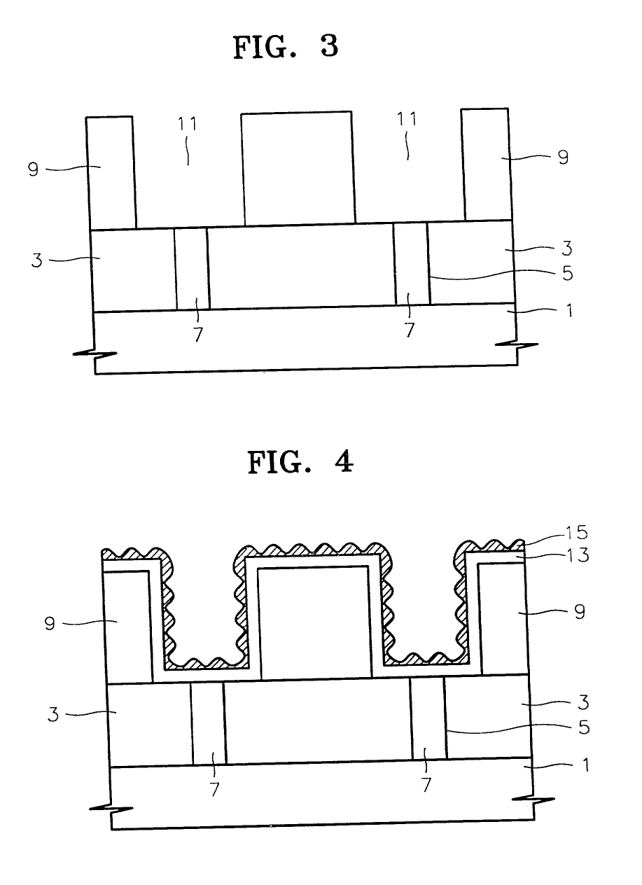

FIG. 2 shows a capacitor of a semiconductor device according to another embodiment of the present invention. The capacitor of FIG. 2 differs from that of FIG. 1 in that a metallic film 23, which is of the same material as conductive material film 13, is on an inner wall of a silicon film 21, i.e., a hemi-spherical grain film (HSG-Si film) so as to form a lower electrode.

The double film including the silicon film and the material film in the lower electrode in the capacitor increases the capacitance value under a negative (−) bias and thus increasing the Cmin/Cmax value. Moreover, being stronger than the polysilicon films used in known capacitors, the conductive material film can make it possible to form a taller lower electrodes in the same area. In particular, owing to the greater strength of metals, a conductive material film thinner than prior polysilicon films can be formed so as to increase inner wall area of the metallic film.

Hereinafter, methods of manufacturing the capacitors of FIGS. 1 and 2 are described.

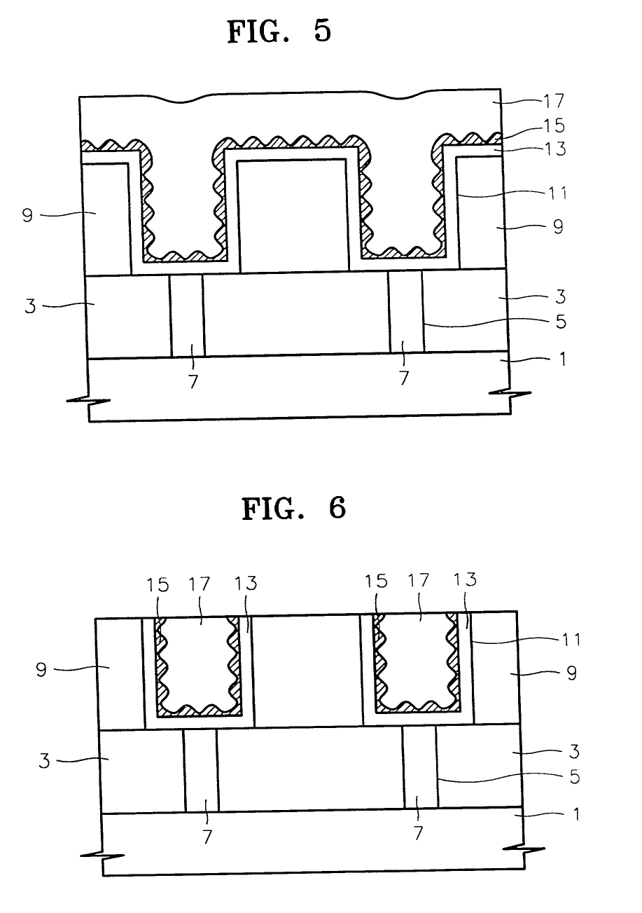

First, with reference to FIGS. 3 to 6, a method for manufacturing the capacitor of FIG. 1 is explained.

Referring to FIG. 3, a coating and patterning of an insulating material on a semiconductor substrate 1 forms a first insulating film 3 having a first contact hole 5. Then, buried conductive layer 7, which electrically connects to substrate 1, is formed in first contact hole 5, and another coating and patterning of an insulating material on buried conductive layer 7 and first insulating film 3 forms a second insulating film 9 having openings 11 exposing the buried conductive layer 7.

Referring to FIG. 4, conventional CVD or sputtering forms conductive material film 13 on the structure of FIG. 3. A preferred thickness of conductive material film 13 is 50 to 500 Å. Conductive material film 13 is formed of a material selected from a group consisting of aluminum, a refractory metal such as Ti, W, and Co, a platinum group metal such as Pt, Ru, Ir and a combination thereof, a platinum group metal oxide such as Ir oxide, Ru oxide and a combination thereof, and suicides of the metals. Preferably, the silicides of the metals are used as conductive material film 13.

The HSG-Si film 15 is formed using a peculiar physical phenomenon which occurs during a transformation of an amorphous silicon into a crystalline silicon. To form the HSG-Si film, after depositing an amorphous silicon film on a semiconductor substrate, a chemical vapor deposition (CVD) using SiH₄ or Si₂H₆ as a silicon source forms silicon seeds on the amorphous silicon film, and then the substrate is annealed for 2 to 10 minutes at 500 to 750° C. A preferable process condition for the CVD has a source gas flow at a rate of 2 to 20 sccm for 2 to 10 minutes in a CVD chamber that is maintained at 600 to 800° C. During the annealing, from the seeds, minute hemispherical grains form on the surface of the amorphous silicon film, so that the HSG-Si film forms. The HSG-SI film formed in such a process has a surface area two or three times larger than a silicon film having a flat surface. An alternative way to form the HSG-Si film is to continue the CVD at the preferable temperature and flow rate condition for 5 to 20 minutes without the annealing.

Referring to FIG. 5, a conventional implanter implants impurities such as P (phosphorous) and As (arsenic) into silicon film 15, if necessary. Preferably, the implanter flows the impurities at a rate of 0.1 to 1.0 sim at 600 to 900° C. for 2 to 10 minutes. Then, a sacrificial film 17 is formed on the structure of FIG. 4 to protect the lower capacitor electrode (conductive material film 13 and silicon film 15) in subsequent capacitor forming processes. To form sacrificial film 17, a conventional spin coating can coat a photoresist, or a conventional low-pressure CVD or plasma CVD can form a SiO₂ film on the structure of FIG. 4. Preferably, the SiO₂ film is used as sacrificial film 17. A preferable thickness of the photoresist or SiO₂ sacrificial film is 2000 to 5000 Å.

Referring to FIG. 6, an etch-back or a chemical mechanical polishing (CMP) removes sacrificial film 17 to expose the second insulating film 9. By doing so, conductive material film 13 and silicon film 15 are removed from the top surface of second insulating film 9. As a result, conductive material film 13 and silicon film 15 remain only on the inner walls of openings 11. Sacrificial film 17 still remains inside openings 11.

Then, a wet-etch removes sacrificial insulating film 17 remaining inside openings 11 and the surrounding second insulating film 9 so as to form a complete lower electrode of FIG. 1. The capacitor of the semiconductor device is completed by forming a dielectric film (not shown) and an upper electrode (not shown) on the overall surface of the structure including conductive material layer 13 and silicon film 15 as the lower electrode.

Referring FIGS. 3, 7 and 8, a method for manufacturing the capacitor of FIG. 2 is explained. First, first insulating film 3 having first contact hole 5, buried conductive layer 7, and second insulating film 9 having openings 11 are formed on semiconductor substrate 1 as described above with reference to FIG. 3.

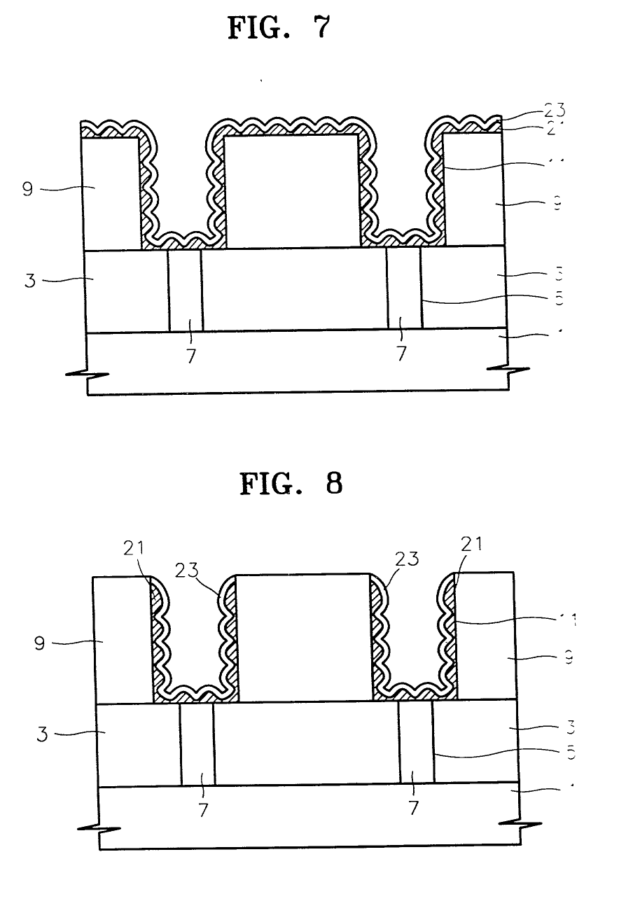

Referring to FIG. 7, silicon film 21, i.e., an HSG-Si film is formed on the structure of FIG. 3, and impurities such as P and As are implanted into silicon film 21, if necessary. Then, conductive material film 23 is formed on silicon film 21, and a sacrificial film (not shown) is formed on the structure of FIG. 7. The impurity implantation and the forming of conductive material film 23, silicon film 21 and the sacrificial film can be performed in the same method as described in the previous embodiment.

Referring to FIG. 8, an etch-back or a chemical mechanical polishing (CMP) removes the sacrificial film to the extent that second insulating film 9 is exposed and removes conductive material film 23 and silicon film 21 from the top surface of second insulating film 9. As a result, conductive material film 23 and silicon film 21 remain only on the inner walls of openings 11. The sacrificial film still remains inside openings 11, until a wet-etch removes the sacrificial insulating film from openings 11 and second insulating film 9 so as to form a complete lower electrode of FIG. 2. To complete the capacitor, a dielectric film (not shown) is formed on the structure of FIG. 2, and an upper electrode (not shown) is formed on the dielectric film.

As mentioned above, using the HSG-Si film increases the effective area of the lower electrode. The Cmin/Cmax value is increased since the conductive material film is used as the lower electrode to decrease charge depletion. Here, table 1 illustrates the effective areas between conventional stack type capacitors and capacitors according to the present invention. The conventional stack type capacitors comprise cylindrical type lower electrodes having HSG-Si films formed on a polysilicon film. The capacitor according to the present invention comprise cylindrical type lower electrodes having HSG-Si films and conductive material films.

TABLE 1

| | first sample | second | first | second |
|---|---|---|---|---|
| | of | sample of | sample | sample of |
| | conventional | conventional | of present | the present |
| | capacitor | capacitor | invention | invention |
| Dimension | 150 × 400 | 120 × 400 | 210 × 400 | 180 × 400 |
| (nm × nm) | | | | |
| Height of lower | 1000 | 1000 | 1000 | 1000 |
| electrode (nm) | | | | |
| Space between | 90 | 120 | 90 | 120 |
| lower electrodes | | | | |
| (nm) | | | | |
| Thickness of | 0 | 0 | 20 | 20 |
| conductive material | | | | |
| film (nm) | | | | |
| Area applied | 1.16 | 1.09 | 1.08 | 1.01 |
| HSG-Si film (μm²) | | | | |
| Effective area (μm²) | 2.32 | 2.18 | 3.94 | 3.71 |

As shown in table 1, the capacitors according to the present invention have effective areas that is increased by about 30 to 40% over that of the conventional stack type capacitors having the same height and distance.

Although the invention has been described with reference to particular embodiments, the description is only an example of the inventor's application and should not be taken as a limitation. Various adaptations and combinations of features of the embodiments disclosed are within the scope of the invention as defined by the following claims.

What is claimed is:

1. A capacitor of a semiconductor device comprised of a lower electrode, a dielectric film, and an upper electrode, wherein the lower electrode comprises a conductive material film and a silicon film.

2. The capacitor of claim 1, wherein the silicon film is a hemi-spherical grain film (HSG-Si film).

3. The capacitor of claim 1, wherein the lower electrode has a cylindrical shape.

4. The capacitor of claim 3, wherein the HSG-Si film is formed on an internal or external wall of the cylindrical shape.

5. The capacitor of claim 1, wherein the conductive material film is selected from a group consisting of an aluminum film, a refractory metal film, a platinum group metal film, a platinum group metal oxide film, and a silicide film of a metal.

6. A method of manufacturing a capacitor of a semiconductor device, comprising:
forming a lower electrode that includes a conductive material film and a silicon film on a semiconductor substrate;
forming a dielectric film on the lower electrode; and
forming an upper electrode on the dielectric film.

7. The method of claim 6, wherein the silicon film is formed of an HSG-Si film.

8. The capacitor of claim 6, wherein the lower electrode has a cylindrical shape.

9. The method of claim 8, wherein the HSG-Si film is formed on an internal or external wall of the cylindrical shape.

10. The method of claim 6, wherein the conductive material film is a film selected from a group consisting of an aluminum film, a refractory metal film, a platinum group metal film, a platinum group metal oxide film, a silicide film of a metal, and any combination of theses films.

11. A method of manufacturing a lower capacitor electrode of a semiconductor device, comprising:
forming an insulating film having an opening;
forming a conductive material film on the insulating film including walls of the opening;
forming a silicon film on the conductive material film;
forming a sacrificial film on the silicon film so as to fill a space within the opening;
removing upper portions of the sacrificial film, the silicon film, and the conductive material film until the insulating film is exposed; and
removing the sacrificial film remaining in the space within the opening and the insulating film.

12. The method of claim 11, wherein the silicon film is formed of an HSG-Si film.

13. The method of claim 11, further comprising implanting impurities in the silicon film after forming the silicon film.

14. The method of claim 11, wherein the conductive material film is a film selected from a group consisting of an aluminum film, a refractory metal film, a platinum group metal film, a platinum group metal oxide film, a silicide film of a metal, and any combination of these films.

15. A method of manufacturing a lower capacitor electrode of a semiconductor device, comprising:
forming an insulating film having a opening;
forming a silicon film on the insulating film and the opening;
forming a conductive material film on the silicon film;
forming a sacrificial film on the conductive material film so as to fill a space within the opening;
removing the sacrificial film, the silicon film, and the conductive material film until the insulating film is exposed; and
removing the sacrificial film remaining in the space within the opening and the insulating film.

16. The method of claim 15, wherein the silicon film is a HSG-Si film.

17. The method of claim 15, further comprising ion-implanting impurities in the silicon film after forming the silicon film.

18. The method of claim 15, wherein the conductive material film is a film selected from a group consisting of an aluminum film, a refractory metal film, a platinum group metal film, a platinum group metal oxide film, a silicide film of a metal, and any combination these films.
